(19) United States
(12) Patent Application Publication
(10) Pub. No.: US 2022/0173256 A1
(43) Pub. Date: Jun. 2, 2022

(54) OPTICAL SENSOR PACKAGES WITH GLASS MEMBERS

(71) Applicant: TEXAS INSTRUMENTS INCORPORATED, Dallas, TX (US)

(72) Inventors: Sreenivasan Kalyani KODURI, Allen, TX (US); Leslie Edward STARK, Heath, TX (US)

(21) Appl. No.: 17/109,980

(22) Filed: Dec. 2, 2020

(51) Int. Cl. H01L 31/0203; H01L 31/02; H01L 31/0216; H01L 31/0232; H01L 31/18

(52) U.S. Cl. CPC H01L 31/0203; H01L 31/02005; H01L 31/186; H01L 31/02327; H01L 31/02162

(57) ABSTRACT

In some examples, an optical sensor package comprises a semiconductor die; an opaque mold compound covering the semiconductor die and having a cavity; and an optical sensor on the semiconductor die and exposed to the cavity. The optical sensor package includes a glass member inside the cavity. The glass member abuts the sensor and a wall of the cavity. The glass member is exposed to an exterior environment of the optical sensor package. The glass member has a thickness approximately equivalent to a depth of the cavity.

### BACKGROUND

Electrical circuits are formed on semiconductor dies and subsequently packaged inside mold compounds to protect the circuits from damage due to elements external to the package, such as moisture, heat, and blunt force. To facilitate communication with electronics external to the package, an electrical circuit within the package is electrically coupled to conductive terminals. These conductive terminals are positioned inside the package but are exposed to one or more external surfaces of the package. By coupling the conductive terminals to electronics external to the package, a pathway is formed to exchange electrical signals between the electrical circuit within the package and the electronics external to the package via the conductive terminals.

### SUMMARY

In some examples, an optical sensor package comprises a semiconductor die; an opaque mold compound covering the semiconductor die and having a cavity; and an optical sensor on the semiconductor die and exposed to the cavity. The optical sensor package includes a glass member inside the cavity. The glass member abuts the sensor and a wall of the cavity. The glass member is exposed to an exterior environment of the optical sensor package. The glass member has a thickness approximately equivalent to a depth of the cavity.

In some examples, a method of manufacturing a semiconductor package comprises obtaining a semiconductor die having an optical sensor; attaching a glass member to the optical sensor; positioning the semiconductor die and the glass member inside a mold chase; establishing contact between a member of the mold chase and a top surface of the glass member; and molding the semiconductor die and the glass member by applying a mold compound inside the mold chase. The contact between the member of the mold chase and the top surface of the glass member prevents the mold compound from flowing onto the top surface of the glass member.

### BRIEF DESCRIPTION OF THE DRAWINGS

For a detailed description of various examples, reference will now be made to the accompanying drawings in which:

FIGS. 1A-10F depict a process flow for manufacturing an optical sensor package having a glass member, in accordance with various examples.

FIGS. 10G-10J are profile cross-sectional views of example optical sensor packages having various example glass members, in accordance with various examples.

FIG. 11 is a flow diagram of a method for manufacturing an optical sensor package having a glass member, in accordance with various examples.

FIGS. 12A-12L depict a process flow for manufacturing an optical sensor package having a glass member, in accordance with various examples.

FIG. 13 is a flow diagram of a method for manufacturing an optical sensor package having a glass member, in accordance with various examples.

### DETAILED DESCRIPTION

Some types of packages are configured to measure various physical properties of an environment, such as temperature, humidity, light, sound, pressure, etc. In many instances, the package includes a sensor that is exposed directly to the environment to be tested. Thus, for example, a package that is configured to measure the temperature of a swimming pool may be positioned in an area of the pool where the sensor will be directly exposed to the pool water. Such packages are referred to herein as sensor packages.

Sensor packages contain sensors, but they also contain other circuitry, such as an analog front-end (AFE) circuit, to process the properties of the environment sensed by the sensor. This circuitry cannot be exposed to the environment, as doing so could damage the circuitry and render it inoperable. Accordingly, sensor packages are fabricated so that the sensor is exposed to the environment, but the remaining circuitry of the package is covered by the mold compound of the package. A sensor package may include a cavity in its mold compound, and the sensor is positioned inside this cavity.

Some sensor packages are configured to detect and measure properties of light, such as the intensity and frequency of light. These sensor packages include optical sensors and thus are called optical sensor packages. Because these optical sensor packages should protect their contents while simultaneously permitting light to reach the optical sensors, the optical sensor packages are often formed of a clear mold compound that is used to expose the optical sensor to light while protecting the remaining semiconductor die and circuitry from physical trauma and other environmental dangers.

These clear mold compounds have numerous disadvantages. The clear mold compounds are inherently unstable, as they typically contain no fillers. In addition, the clear mold compounds can be sensitive to moisture and introduce stress to the optical sensor package due to severe gradients in the coefficient of thermal expansion. Furthermore, such clear mold compounds require complex and expensive manufacturing equipment, processes, and materials. Further still, these clear mold compounds are disadvantageous because they tend to form air bubbles, become discolored, and lose clarity over time, thus negatively affecting the measurement accuracy and longevity of the optical sensor package.

Optical sensor packages have other problems as well. For example, at least some optical sensor packages include cavities in which optical sensors are positioned, and due to sizing challenges in equipment used to create these cavities, the cavities tend to be undesirably large. Because the cavities are undesirably large, a single optical sensor package can only accommodate a single cavity. If additional cavities are included, then the optical sensor package is increased in size to accommodate the additional cavities, typically to an unacceptable degree.

This disclosure describes various examples of an optical sensor package that mitigates the challenges described above. In examples, the optical sensor package includes a glass member that abuts an optical sensor on a semiconductor die in the optical sensor package. An opaque mold compound covers the semiconductor die, but it does not cover the glass member, so that the glass member is exposed to an external environment of the optical sensor package. By using an opaque mold compound instead of a clear mold compound, the superior protective advantages of opaque mold compounds are realized. Further, because glass is used instead of the clear mold compound to protect the optical sensor, the optical path to the optical sensor remains stable, clear, free of discoloration, and free of air bubbles. In this way, the superior qualities of glass are leveraged to improve the measurement accuracy of the optical sensor package for extended lengths of time.

In addition, glass members are produced independently of the optical sensor package fabrication process, without using expensive equipment, processes, and materials. Because the glass members are produced independently of the optical sensor package fabrication process, the glass members may be designed and manufactured in any suitable manner, with various shapes (e.g., horizontal cross-sections that are circular, elliptical, rectangular, rectangular with rounded corners), sizes (e.g., different combinations of horizontal cross-sectional area and depth to accommodate light rays having different angles of incidence), colors (e.g., to filter target wavelength colors), and other properties. The glass members may be formed using a variety of suitable techniques, such as laser cutting, chemical etching, sawing, casting, etc. Anisotropic etching techniques may be used to form special features, such as slants or steps, in the outer surfaces of the glass members to facilitate locking of the glass members with the opaque mold compounds. Coatings may be applied to the glass members to reduce reflective losses and/or for their filtering properties.

Because of such flexibility in glass member design and manufacture, the glass members may have small sizes. The glass members may be coupled to optical sensors on semiconductor dies and then be subjected to a molding process, where the top surfaces of the glass members make contact with the mold chase and thus preclude the flow of mold compound onto the top surfaces of the glass members. In this way, the glass members form cavities in the mold compounds, and because the glass members are small in size, the resulting cavities are also significantly smaller in size than those found in traditional optical sensor packages. Accordingly, the ratio of optical sensor number to optical sensor package size is substantially increased relative to such ratios in traditional optical sensor packages.

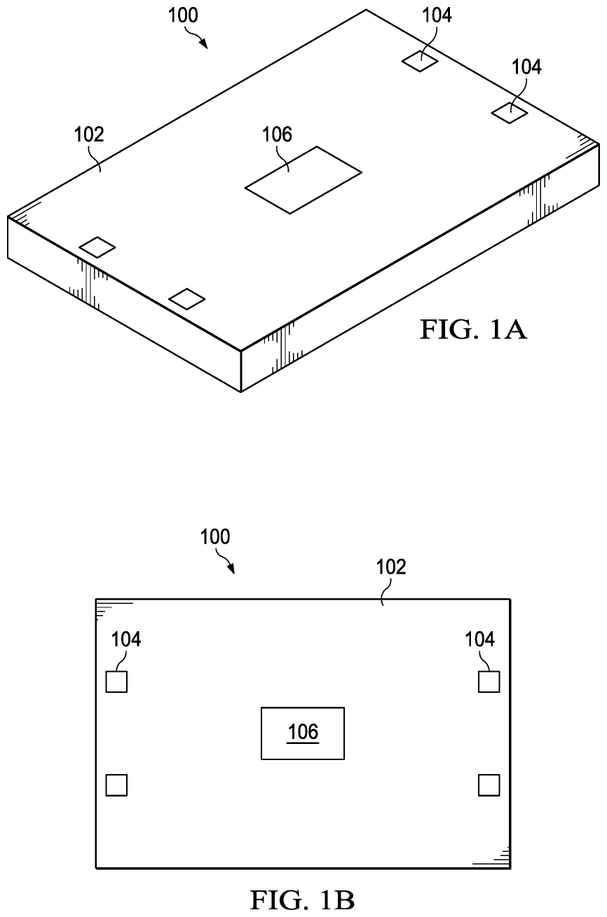

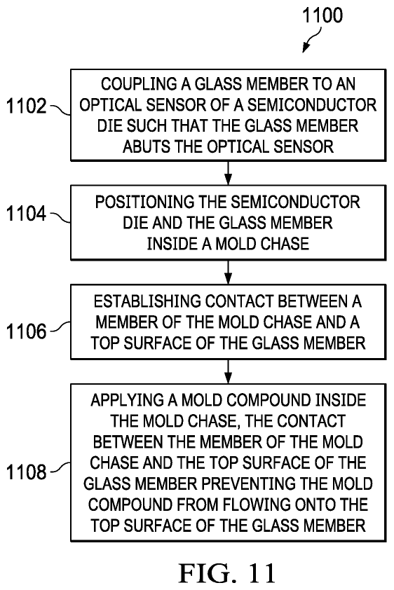

FIGS. 1A-10F depict a process flow for manufacturing an optical sensor package having a glass member, in accordance with various examples. FIG. 11 is a flow diagram of a method 1100 for manufacturing an optical sensor package having a glass member, in accordance with various examples. Accordingly, the method 1100 is now described in tandem with the process flow of FIGS. 1A-10F.

The method 1100 includes coupling a glass member to an optical sensor of a semiconductor die such that the glass member abuts the optical sensor (1102). FIG. 1A is a perspective view of an example semiconductor die 100 having an active surface 102. The active surface 102 includes bond pads 104 and an optical sensor 106. The optical sensor 106 is any suitable type of optical sensor capable of detecting any suitable type of light, such as visible light and infrared light. The optical sensor 106 may be of any suitable size and shape. In examples, the optical sensor 106 has a size ranging from 1 mm² to 100 mm², with a sensor smaller than this range possibly capturing inadequate light and a sensor larger than this range being more susceptible to defects and higher costs. The active surface 102 may also include circuitry (not expressly shown), such as an analog front end (AFE) coupled to the optical sensor 106. Such circuitry may be used to process signals encoding light detected by the optical sensor 106. FIG. 1B is a top-down view of the structure of FIG. 1A.

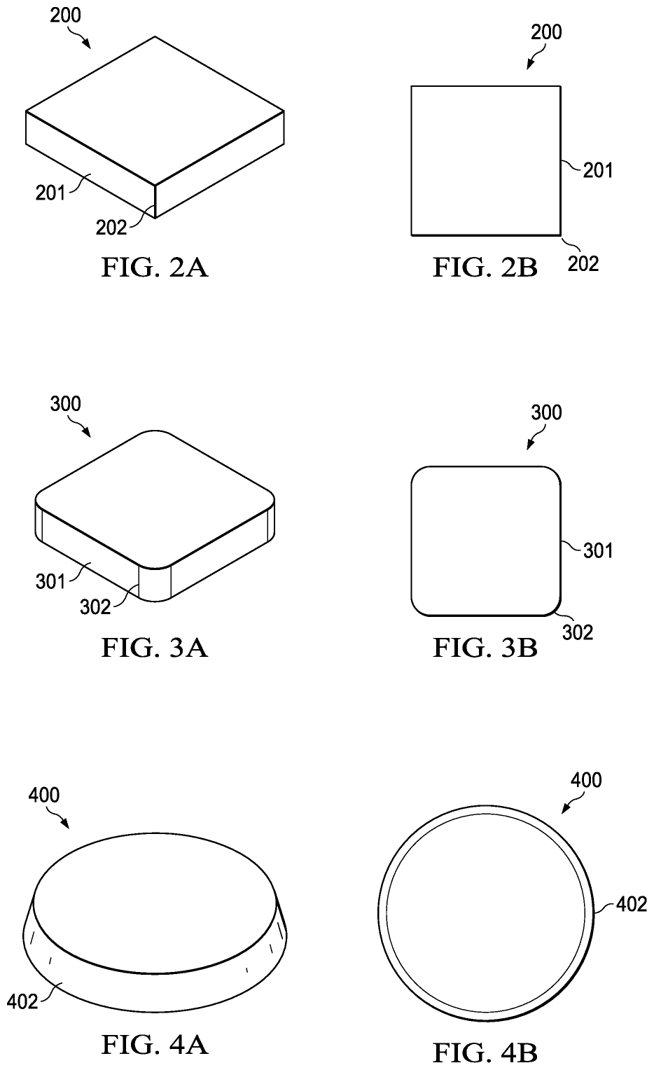

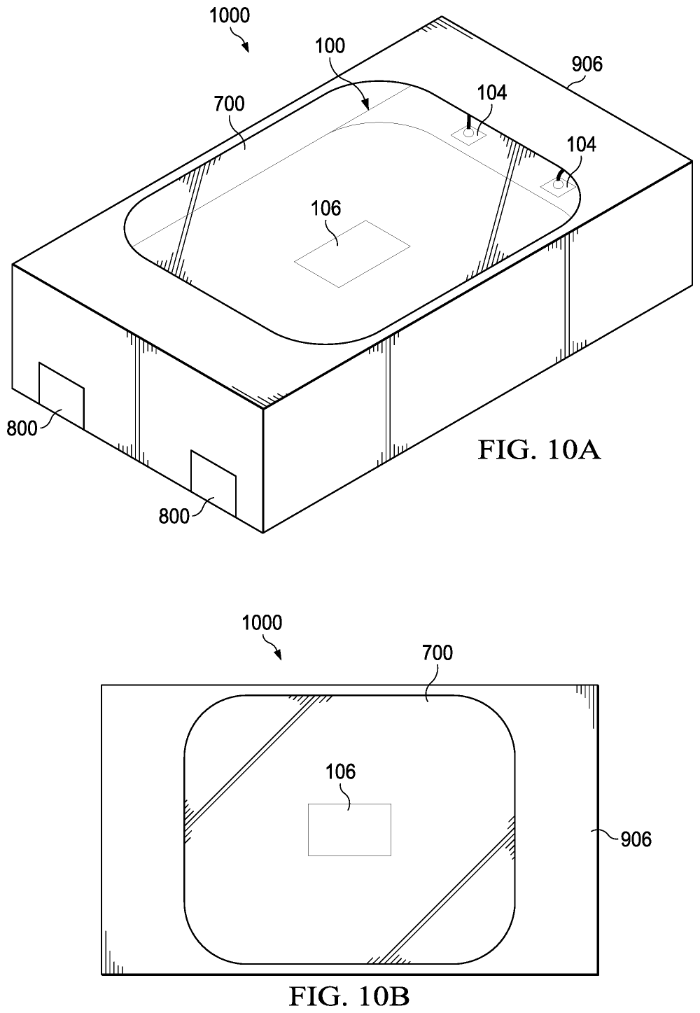

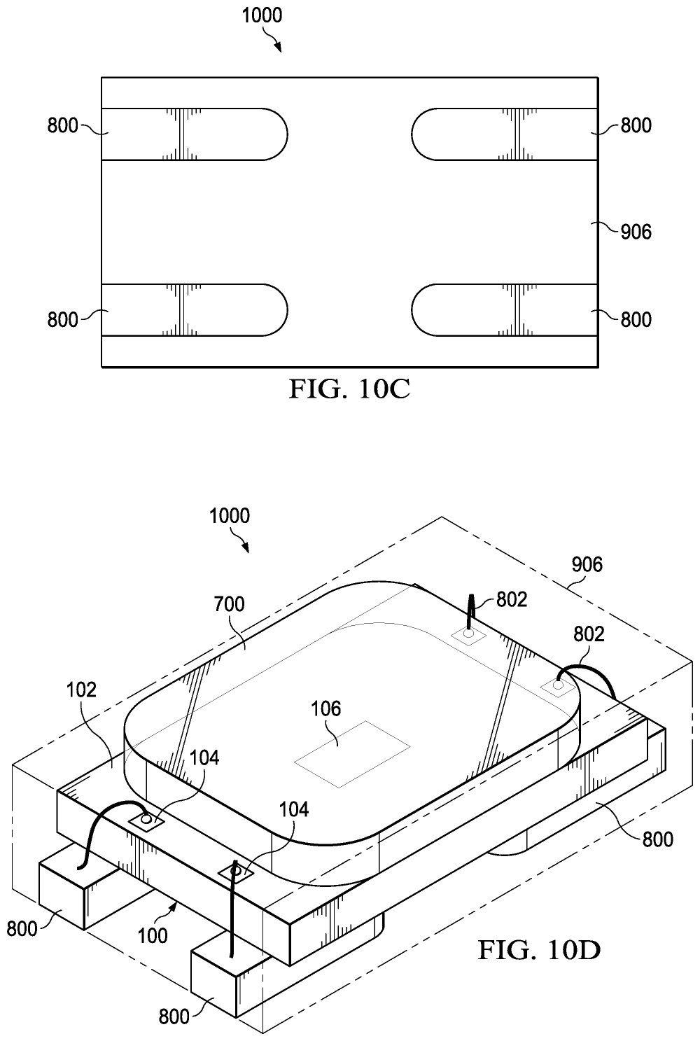

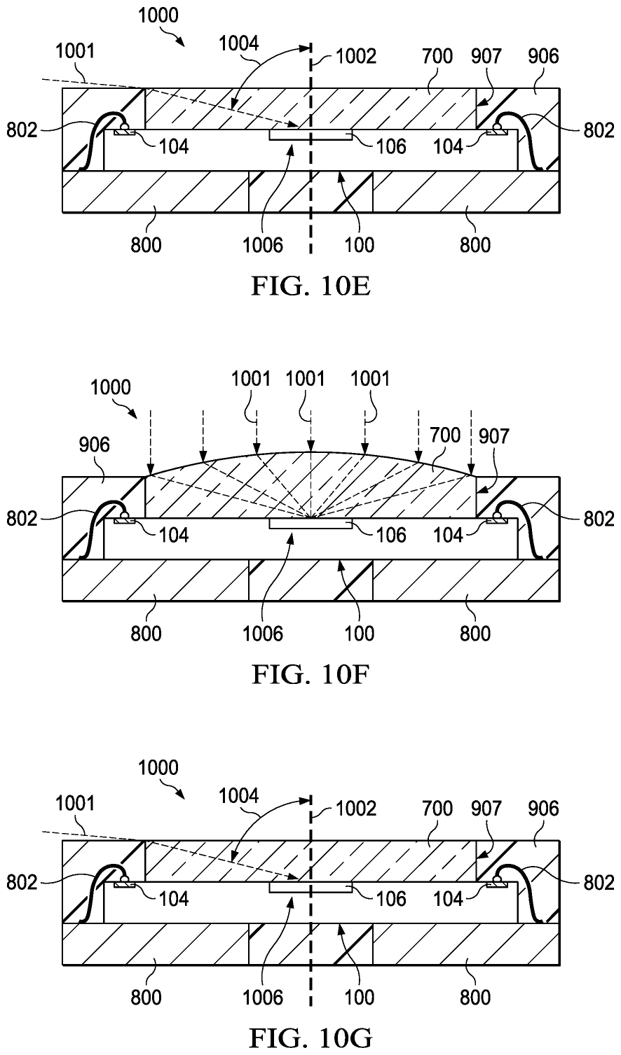

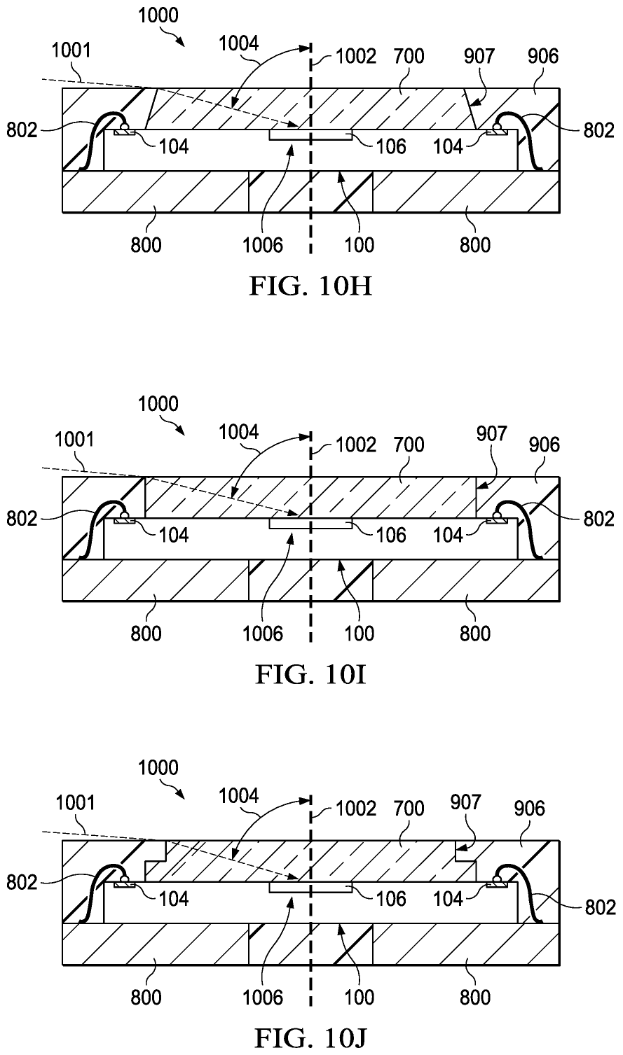

FIG. 2A is a perspective view of an example glass member 200. A horizontal cross-section of the glass member 200 is rectangular, although other shapes are contemplated. In examples, the glass member 200 has an approximately uniform horizontal cross-sectional area throughout its thickness, although variations in this area in different horizontal planes are contemplated. In examples, the glass member 200 has multiple, flat outer surfaces 201, as shown. In examples, the glass member 200 has corners 202 that are approximately right angles. The dimensions of the glass member 200 may vary and are described in greater detail below with respect to FIGS. 10E and 10F. FIG. 2B is a top-down view of the structure of FIG. 2A.

FIG. 3A is a perspective view of an example glass member 300. A horizontal cross-section of the glass member 300 is rectangular with rounded corners, although other shapes are contemplated. In examples, the glass member 300 has an approximately uniform horizontal cross-sectional area throughout its thickness, although variations in this area in different horizontal planes are contemplated. In examples, the glass member 300 has multiple, flat outer surfaces 301, as shown. In examples, the glass member 300 has corners 302 that are rounded. The dimensions of the glass member 300 may vary and are described in greater detail below with respect to FIG. 10E and 10F. FIG. 3B is a top-down view of the structure of FIG. 3A.

FIG. 4A is a perspective view of an example glass member 400. A horizontal cross-section of the glass member 400 is circular, although other shapes are contemplated. In examples, the glass member 400 has a horizontal cross-sectional area that varies throughout its thickness, although approximate uniformity in the horizontal cross-sectional area throughout the thickness of the glass member 400 is contemplated. In examples, the glass member 400 has a slanted outer surface 402, as shown. Such a slanted outer surface 402 is helpful in locking the glass member 400 into the mold compound that will subsequently be applied to form an optical sensor package, thus making it more difficult for the glass member 400 to become dislodged from the mold compound. For example, when the wider portion of the glass member 400 is positioned closer to the optical sensor of the package and the narrower portion of the glass member 400 is positioned closer to a top surface of the package, the glass member 400 is unlikely to become dislodged. The dimensions of the glass member 400 may vary and are described in greater detail below with respect to FIGS. 10E and 10F. FIG. 4B is a top-down view of the structure of FIG. 4A.

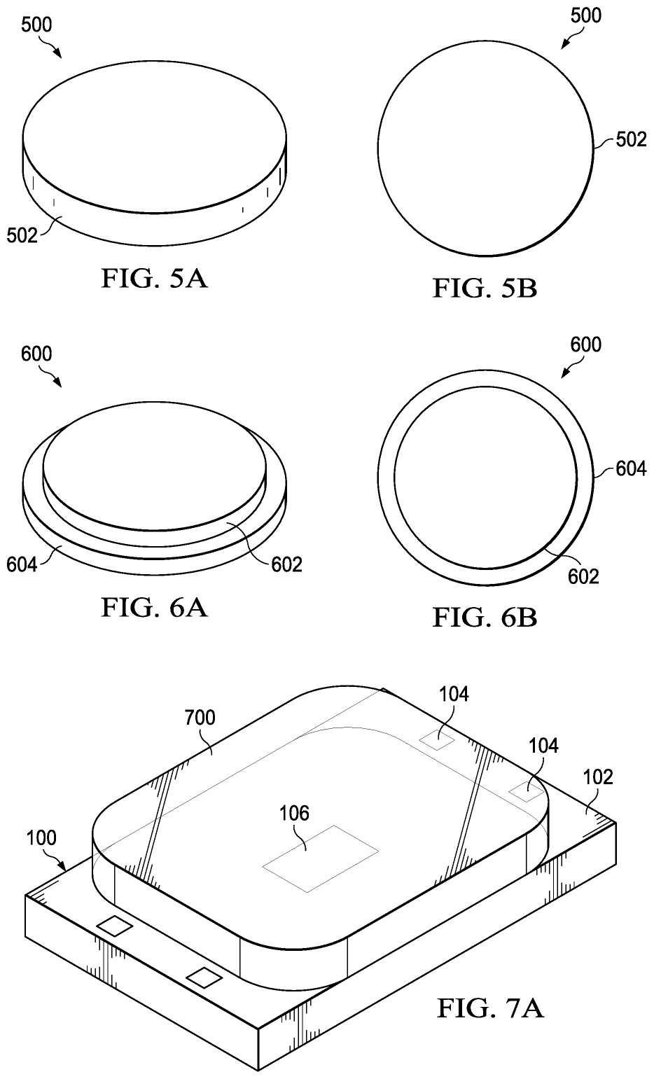

FIG. 5A is a perspective view of an example glass member 500. A horizontal cross-section of the glass member 500 is circular, although other shapes are contemplated. In examples, the glass member 500 has an approximately uniform horizontal cross-sectional area throughout its thickness, although variations in this area in different horizontal planes are contemplated. In examples, the glass member 500 has a non-slanted outer surface 502, as shown. The dimensions of the glass member 500 may vary and are described in greater detail below with respect to FIGS. 10E and 10F. FIG. 5B is a top-down view of the structure of FIG. 5A.

FIG. 6A is a perspective view of an example stepped cylindrical glass member 600. A horizontal cross-section of the glass member 600 is circular, although other shapes are contemplated. In examples, the glass member 600 has multiple, different horizontal cross-sectional areas throughout its thickness. In examples, the glass member 600 has multiple, rounded outer surfaces 602, 604, each corresponding to a different horizontal diameter. These multiple, rounded outer surfaces 602, 604 may be formed in a stepped pattern, as shown, which locks the glass member 600 with the mold compound that is later applied, thus mitigating the risk of the glass member 600 becoming dislodged from the optical sensor package. In both FIGS. 4A and 6A, the glass member 400, 600 is wider at the bottom and narrower at the top, making dislodging difficult after a mold compound is applied. For example, when the wider portion of the glass member 600 is positioned closer to the optical sensor of the package and the narrower portion of the glass member 600 is positioned closer to a top surface of the package, the glass member 600 is unlikely to become dislodged. The dimensions of the glass member 600 may vary and are described in greater detail below with respect to FIGS. 10E and 10F. FIG. 6B is a top-down view of the structure of FIG. 6A.

The glass members depicted in FIGS. 2A-6B may be composed of any suitable type of glass. In some examples, the glass members of FIGS. 2A-6B are composed of glass-filled polymer. In some examples, the glass members of FIGS. 2A-6B are composed of crystal. Other types of glass are contemplated and included in the scope of this disclosure. In examples, the glass members are formed by cutting (e.g., laser dicing, sawing), casting, or etching a sheet or wafer of glass. The slanted and/or stepped outer surfaces described above with respect to FIGS. 4A and 6A may be formed, for instance, using anisotropic etching techniques. In examples, the glass members are formed separately from the optical sensor package described herein. The glass members may be colored to filter particular wavelengths of light. For example, coloring the glass member red may filter out red light. In examples, the glass members may be coated (e.g., on a top surface of the glass member) with one or more coats (e.g., coats composed of thin polymer films that can absorb or reflect specific target frequencies) to filter light of a target frequency or range of frequencies. In examples, the glass members shown in the drawings (e.g., FIGS. 2A-6B) and described throughout the specification have a horizontal area ranging from 5 mm2 to 600 mm2. A glass member larger than this range may be too large to fit on a semiconductor die or may interfere with the wirebonding process, and a glass member smaller than this range may be too small to permit adequate amounts of light to reach the sensor.

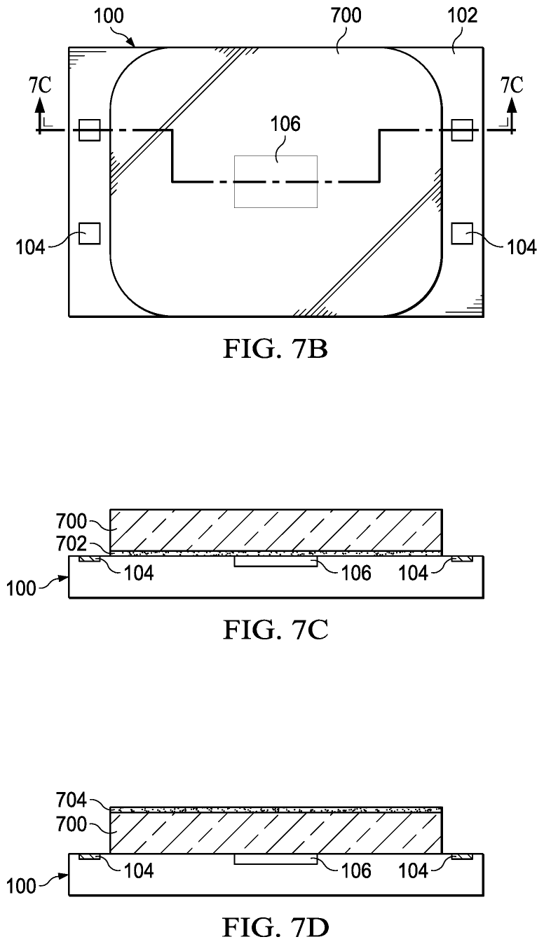

FIG. 7A depicts an example glass member 700 coupled to the semiconductor die 100, and more specifically, to the optical sensor 106 (not visible in FIG. 7A) of the semiconductor die 100. The glass member 700 is representative of any of the glass members depicted in FIGS. 2A-6B. Any suitable technique may be used to couple the glass member 700 to the optical sensor 106 and, more generally, to the semiconductor die 100, including a transparent optical adhesive; direct bonding; surface activated bonding; anodic bonding; eutectic bonding; glass frit bonding; adhesive bonding; thermocompression bonding; reactive bonding; and transient liquid phase diffusion bonding. Other techniques are also contemplated. Thus, in some examples, an adhesive is positioned between the glass member 700 and the optical sensor 106, and so the glass member 700 abuts the adhesive. In other examples, there is no adhesive between the glass member 700 and the optical sensor 106, and so the glass member 700 abuts the optical sensor 106.

FIG. 7B is a top-down view of the structure of FIG. 7A. FIG. 7C is a profile, cross-sectional view of the structure of FIG. 7A. In the example of FIG. 7C, an adhesive 702 is positioned between the glass member 700 and the optical sensor 106, and thus the adhesive 702 abuts both the glass member 700 and the optical sensor 106. FIG. 7D is another profile, cross-sectional view of the structure of FIG. 7A. In the example of FIG. 7D, there is no adhesive present between the glass member 700 and the optical sensor 106. However, a coating 704, such as the coatings described above used for wavelength filtering purposes, is positioned on a top surface of the glass member 700.

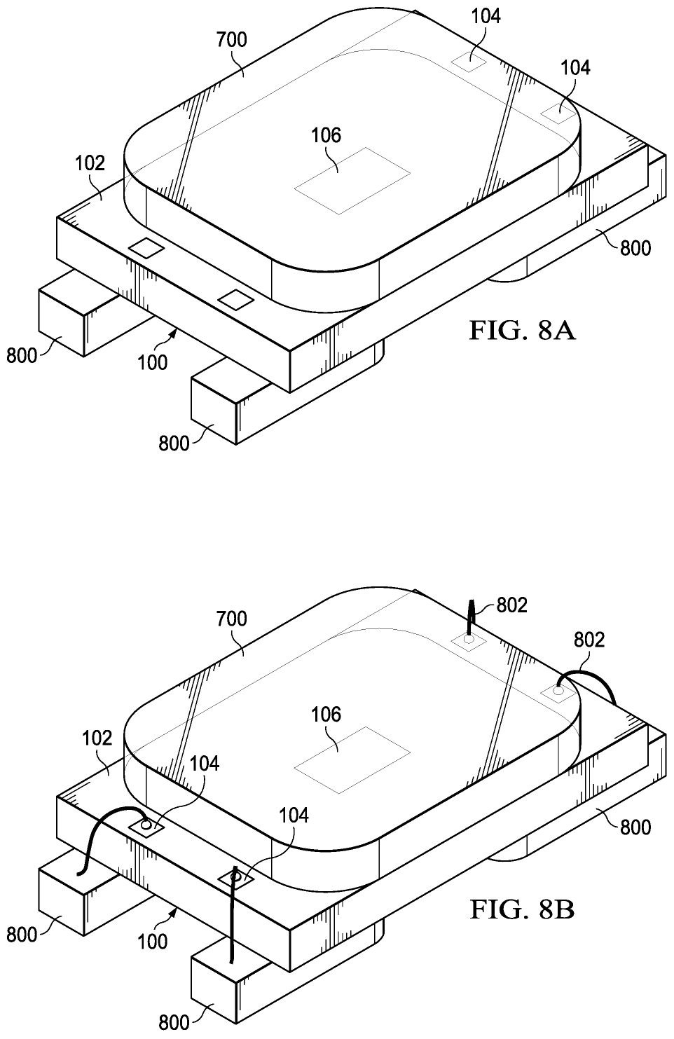

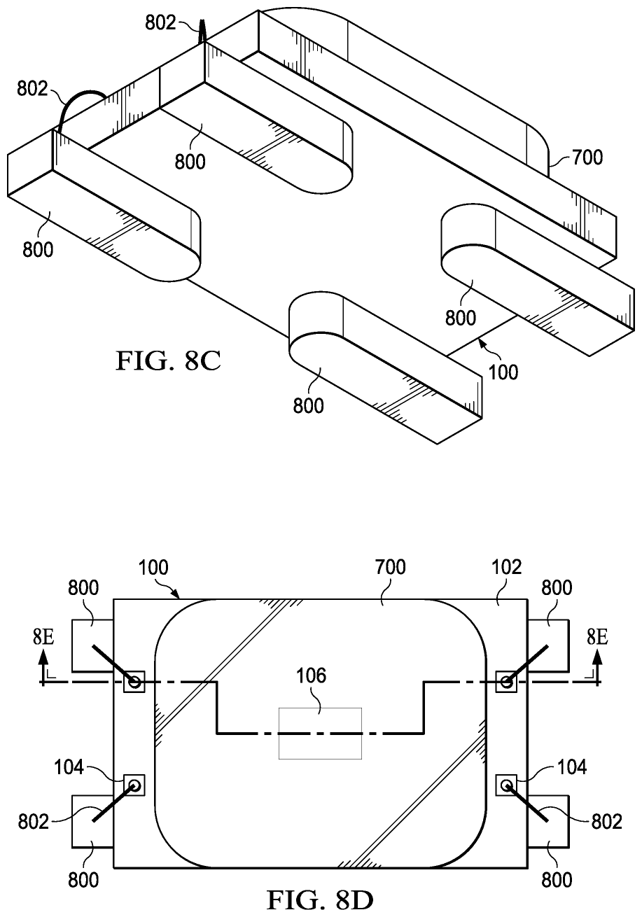

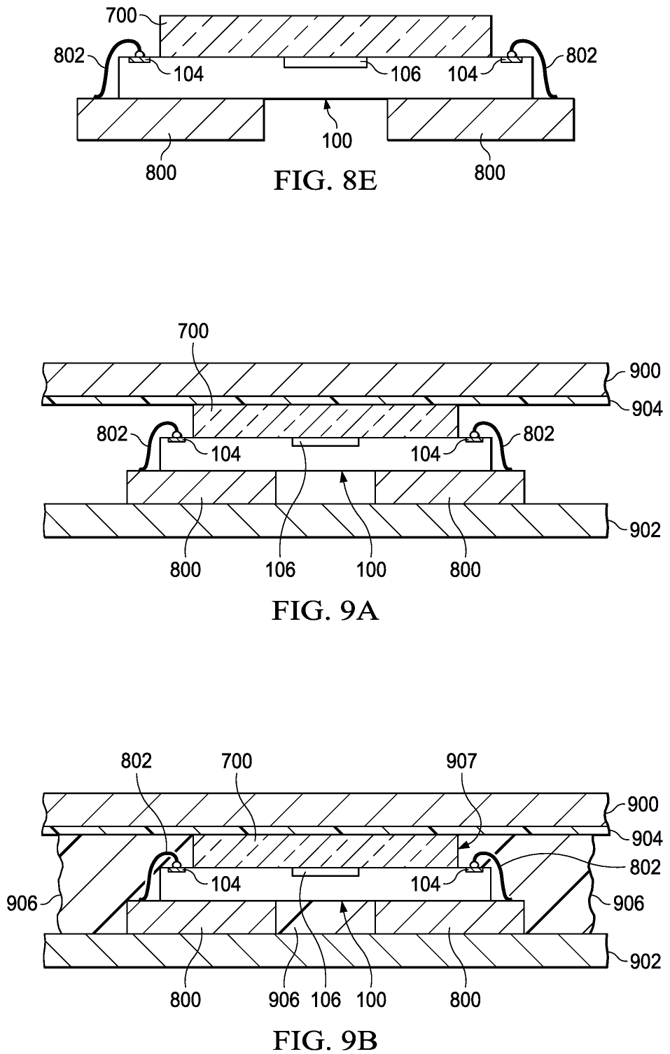

The structure of FIG. 7A may be coupled to a lead frame. FIG. 8A is a perspective view of the structure of FIG. 7A coupled to conductive terminals 800 (e.g., leads) of a lead frame, for example, in a lead frame strip. In other examples, the structure of FIG. 7A may be coupled to a die pad which, in turn, may be coupled to conductive terminals. In FIG. 8B, bond wires 802 are coupled between the conductive terminals 800 and the bond pads 104. The bond wires 802 may be composed of, e.g., gold, aluminum, copper, palladium coated copper (PCC), etc. FIG. 8C is another perspective view of the structure of FIG. 8B. FIG. 8D is a top-down view of the structure of FIG. 8B. FIG. 8E is a profile, cross-sectional view of the structure of FIG. 8B.

The method 1100 includes positioning the semiconductor die and the glass member inside a mold chase (1104). The method 1100 also includes establishing contact between a member of the mold chase and a top surface of the glass member (1106). FIG. 9A is a profile, cross-sectional view of the structure of FIG. 8B being positioned inside a mold chase. The mold chase includes members 900, 902. A film 904 (e.g., a polymer film) is optionally positioned between the member 900 and the glass member 700 to prevent damage to the glass member 700 by the member 900. When the member 900 is lowered as shown, the bottom surface of the member 900 abuts the top surface of the glass member 700. Alternatively, if a film 904 is used, then when the member 900 is lowered as shown, the bottom surface of the film 904 abuts the top surface of the glass member 700. When a film is used, the film may be considered part of the mold chase member 900. A mold compound is then applied (e.g., injected) into the mold chase.

The method 1100 includes applying a mold compound inside the mold chase, with the contact between the member of the mold chase and the top surface of the glass member preventing the mold compound from flowing onto the top surface of the glass member (1108). FIG. 9B is a profile, cross-sectional view of the structure of FIG. 9A, but with an opaque mold compound 906 covering the structure that is positioned inside the mold chase. As shown, the contact between the top surface of the glass member 700 and the bottom surface of either the member 900 or the film 904 prevents mold compound 906 from flowing over the top surface of the glass member 700. However, the mold compound 906 still flows over the remaining portions of the structure positioned in the mold chase, such as the semiconductor die 100, the bond wires 802, and the conductive terminals 800. Because the mold compound 906 flows around, but not on top of, the glass member 700, the mold compound 906 forms a cavity 907 inside which the glass member 700 rests. The glass member 700 thus abuts the optical sensor 106 and at least one wall of the cavity 907. In some examples, the glass member 700 abuts multiple walls of the cavity 907, depending on the shapes of the glass member 700 and the cavity 907. Because the cavity 907 is formed by the glass member 700, the cavity 907 and the glass member 700 have the same dimensions, shapes, and volumes in at least some examples. Because the glass member 700 covers the optical sensor 106, the mold compound does not cover the optical sensor 106.

After the mold compound is applied, a singulation technique is performed to produce individual optical sensor packages. FIG. 10A is a perspective view of such an optical sensor package 1000. The optical sensor package 1000 includes the mold compound 906, the glass member 700, and the conductive terminals 800. The glass member 700, and specifically a top surface of the glass member 700, is exposed to an exterior environment of the optical sensor package 1000. The conductive terminals 800 are exposed to an exterior surface of the optical sensor package 1000 and facilitate communication between the semiconductor die 100 inside the optical sensor package 1000 and one or more electronic devices outside the optical sensor package 1000, such as via a printed circuit board (PCB). FIG. 10B is a top-down view of the optical sensor package 1000, and FIG. 10C is a bottom-up view of the optical sensor package 1000. FIG. 10D is a reproduction of FIG. 10A but with visibility into the structures covered by the mold compound 906.

The dimensions of the glass member 700 may vary, depending on the size of the optical sensor package 1000, the size of the optical sensor 106, the size of semiconductor die 100, and the application in which the optical sensor package 1000 is to be deployed. In some examples, the glass member 700 is sized so that the optical sensor 106 is able to capture a wide angle of light, and in other examples, the glass member 700 is sized so that the optical sensor 106 is able to capture a narrow angle of light. FIG. 10E is a profile, cross-sectional view of parts of the optical sensor package 1000, including the mold compound 906, the optical sensor 106, and the glass member 700. A normal 1002 extends through a center of the optical sensor 106. A representative light ray 1001 enters the glass member 700 and strikes the optical sensor 106 with an angle of incidence 1004. Because the light ray 1001 passes through the glass member 700, the dimensions of the glass member 700 affect the amount and angle of light that the optical sensor 106 can capture. For example, for a fixed depth of the glass member 700, a narrower glass member 700 (e.g., smaller diameter, smaller width, or smaller length) will capture only light rays having relatively small angles of incidence 1004, while a wider glass member 700 (e.g., larger diameter, larger width, or larger length) will capture light rays having both relatively small and relatively large angles of incidence 1004. Similarly, for a fixed diameter, width, or length of the glass member 700, a deeper glass member 700 will limit the optical sensor 106 to detecting light rays having a relatively small angle of incidence 1004, while a shallower glass member 700 will permit the optical sensor 106 to detect light rays having both relatively small and large angles of incidence 1004. In some applications, it may be desirable for the optical sensor 106 to be able to detect light rays over a limited range of angles of incidence 1004 (e.g., 0 degrees to 30 degrees, 0 degrees to 20 degrees, 0 degrees to 10 degrees, 0 degrees to 5 degrees). In other applications, it may be desirable for the optical sensor 106 to be able to detect light rays over a relatively large range of angles of incidence 1004 (e.g., 0 degrees to 80 degrees, 0 degrees to 75 degrees, 0 degrees to 70 degrees, 0 degrees to 65 degrees). Thus, the dimensions of the glass member 700 may be selected to achieve a target range of angles of incidence. In examples, these dimensions include depth of the glass member 700, as well as the diameter, length, and/or width (e.g., horizontal cross-sectional area) of the glass member 700 at or near the top surface of the glass member 700. The diameter, length, and/or width of the glass member 700 at lower levels of the glass member 700, for example at the bottom surface of the glass member 700, may not affect the angles of light that the optical sensor 106 is able to detect.

The features (e.g., physical dimensions) described above for the glass member 700 may also be determined based in part on the relative refractive indices of air and glass. The refractive index of glass is higher than that of air, and so incident light rays may bend as they enter the glass member 700. The glass member 700 dimensions may be selected with relative refractive indices as a consideration.

The example scenario of FIG. 10E assumes that the light ray 1001 should strike a center of the optical sensor 106. However, it may be sufficient for the light ray 1001 to strike a periphery of the optical sensor 106, for example, at an area marked by numeral 1006. In such examples, the diameter, width, and/or length of the glass member 700 may not need to be as large as would be the case if the light ray 1001 needs to strike the center of the optical sensor 106. Thus, performance of the optical sensor 106 at the periphery of the optical sensor 106 is a relevant consideration when determining dimensions of the glass member 700.

In some examples, the glass member 700 may be shaped to collect greater amounts of light. For example, FIG. 10F is a reproduction of the structure of FIG. 10E, except that the glass member 700 has a top surface with a convex shape, thus causing light rays from the environment of the optical sensor package 1000 to bend toward the optical sensor 106. Such a convex shape is arched and thus confers the added benefit of structural integrity relative to glass members 700 having flat top surfaces (e.g., the glass members shown in FIGS. 2A-6B). The specific curvature used may depend on the application, the size of the optical sensor 106 relative to the glass member 700, the focal point at the optical sensor 106 and thus the thickness of the glass member 700, etc. In some examples, the curvature of a top surface of the glass member 700 may be flat or may have a convex shape with a radius of curvature ranging from 10 cm to 15 cm. Thus, curves in the glass member 700 may be manipulated along with dimensions and other features of the glass member 700 to cause light rays 1001 to strike the optical sensor 106. In some examples, during the molding process, to prevent mold compound from covering the curved surface of the glass member 700 of FIG. 10F, a polymer film or other compressible material of sufficient thickness may be coupled to the top member of the mold chase and may be aligned to contact solely the glass member 700.

FIGS. 10G-10J are profile cross-sectional views of example optical sensor packages having various example glass members, in accordance with various examples. Specifically, each of FIGS. 10G-10J is similar to FIG. 10E but with a different shape for the glass member 700 and for the cavity 907. The structure of FIG. 10G includes a glass member 700 and cavity 907 consistent with the structure of FIGS. 2A and 2B. The structure of FIG. 10H includes a glass member 700 and cavity 907 consistent with the structure of FIGS. 4A and 4B. The structure of FIG. 10I includes a glass member 700 and cavity 907 consistent with the structure of FIGS. 5A and 5B. The structure of FIG. 10J includes a glass member 700 and cavity 907 consistent with the structure of FIGS. 6A and 6B.

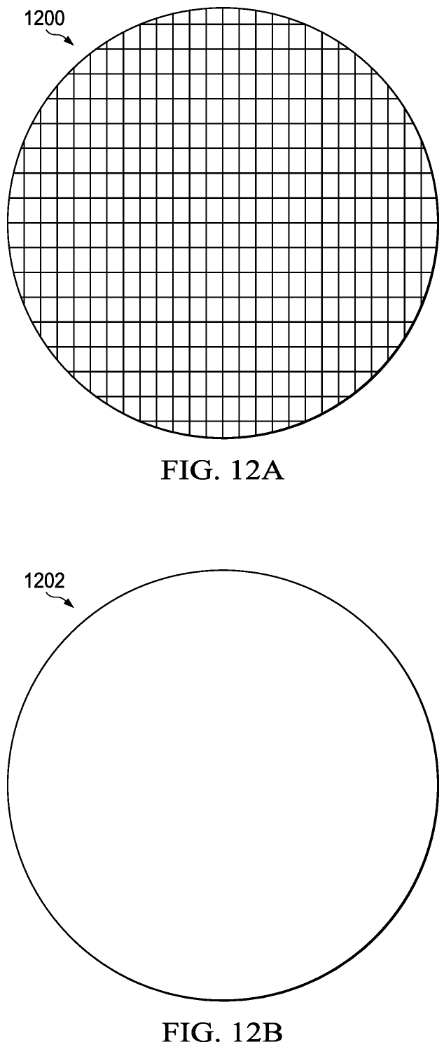

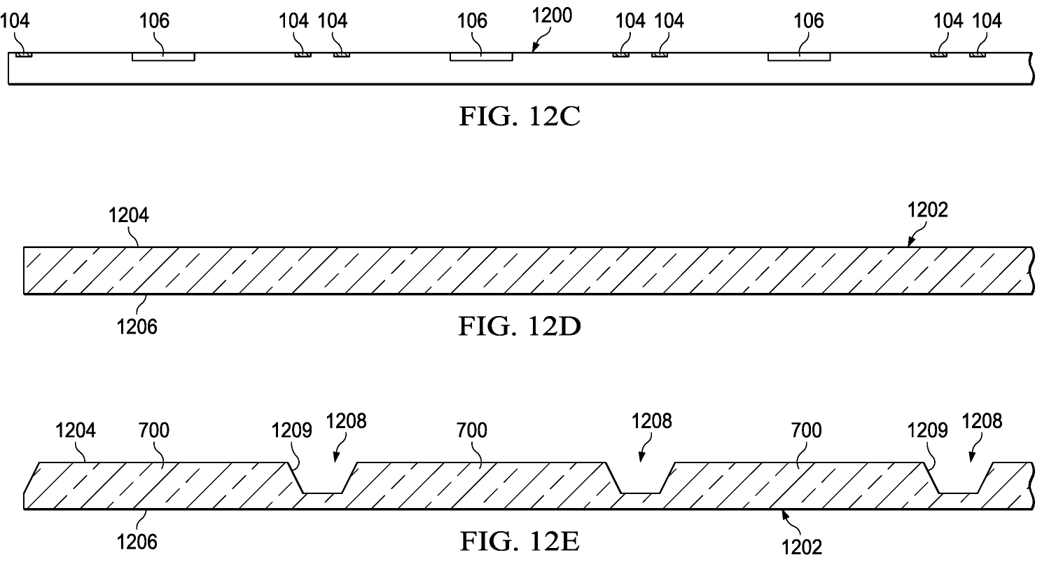

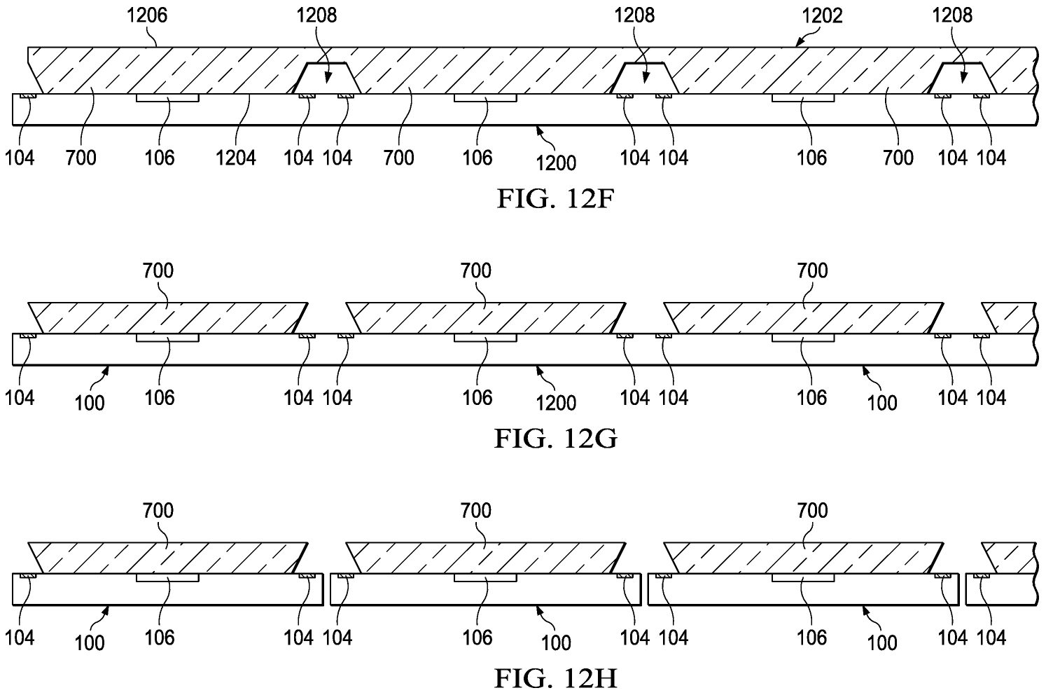

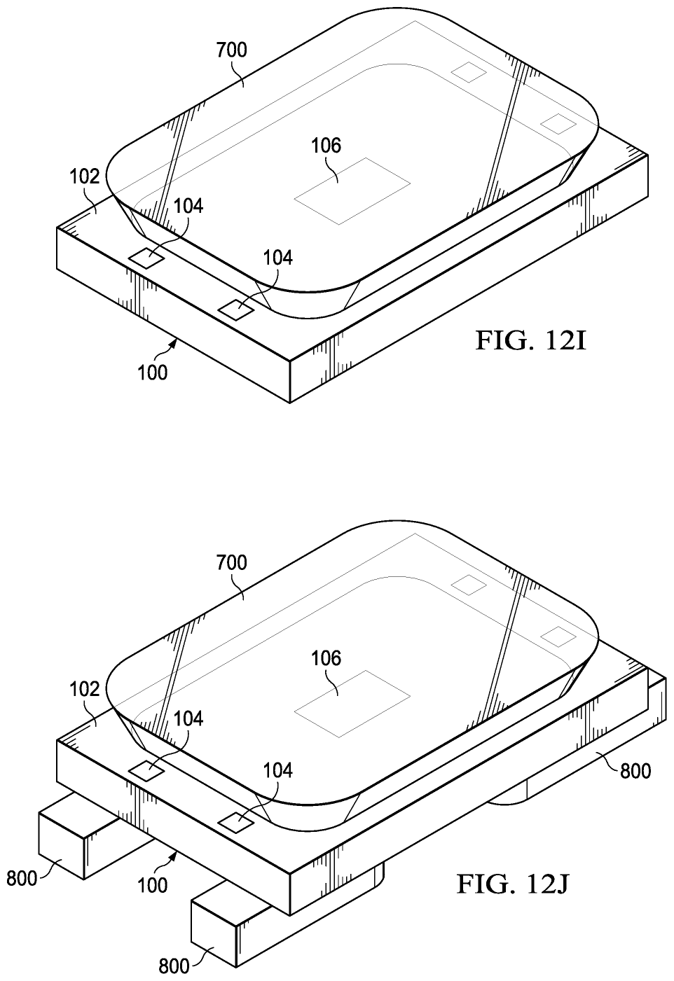

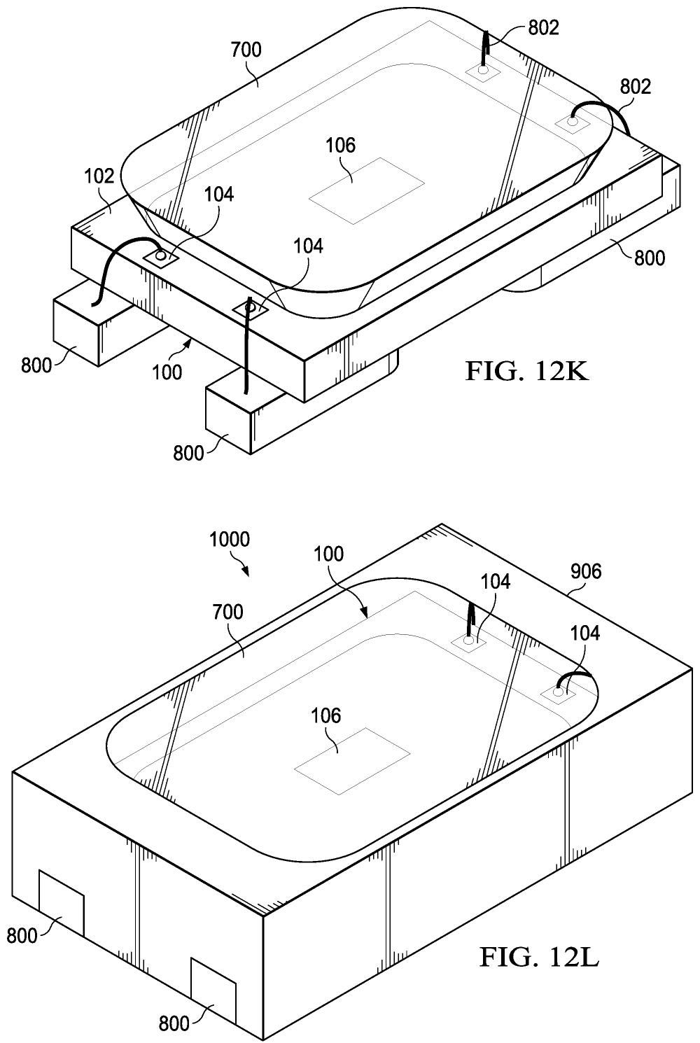

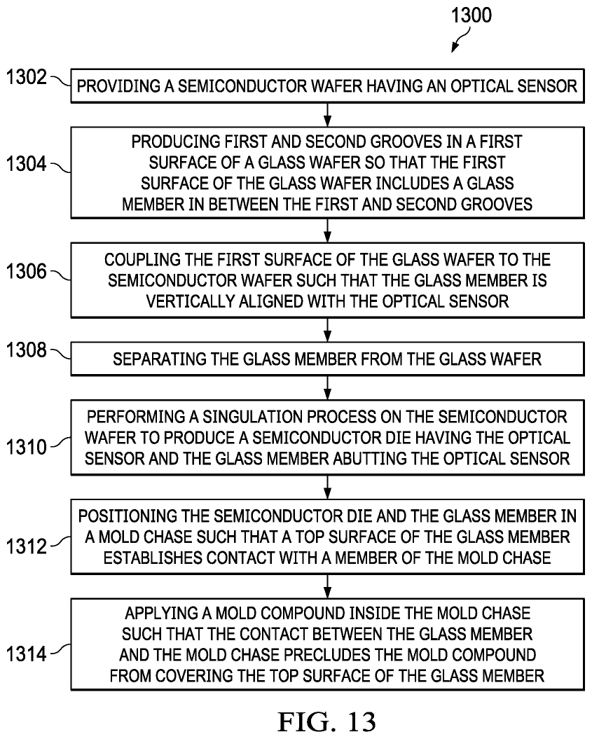

FIGS. 12A-12L depict a process flow for manufacturing an optical sensor package having a glass member, in accordance with various examples. FIG. 13 is a flow diagram of a method 1300 for manufacturing an optical sensor package having a glass member, in accordance with various examples. Accordingly, the method 1300 is now described in tandem with the process flow of FIGS. 12A-12L.

The method 1300 includes providing a semiconductor wafer having an optical sensor (1302). FIG. 12A is a top-down view of a semiconductor wafer 1200, such as a silicon wafer. The semiconductor wafer 1200 includes a plurality of unsingulated semiconductor dies that are coupled to each other via scribe streets, with each of at least some semiconductor dies having at least one optical sensor formed thereupon. FIG. 12B is a top-down view of a glass wafer 1202, such as a glass-filled polymer wafer or a crystal wafer. FIG. 12C is a profile, cross-sectional view of the semiconductor wafer 1200 having bond pads 104 and optical sensors 106 formed thereupon. FIG. 12D is a profile, cross-sectional view of the glass wafer 1202. As explained above, the glass wafer 1202 may have a particular color or coating to filter light of certain wavelength ranges. The glass wafer 1202 has a top surface 1204 and a bottom surface 1206 opposite the top surface 1204.

The method 1300 includes producing first and second grooves in a first surface of a glass wafer so that the first surface of the glass wafer includes a glass member in between the first and second grooves (1304). FIG. 12E is a profile, cross-sectional view of the glass wafer 1202 having grooves 1208 produced in the top surface 1204 of the glass wafer 1202. The grooves 1208 may be produced using an anisotropic etch, for example, although other techniques are contemplated. In some examples, the grooves 1208 have slanted walls 1209, as shown. Glass members 700 are positioned in between the grooves 1208. The glass members 700 in this example are similar to the glass member 400 of FIG. 4A in that the glass members 700 have slanted edges. In other examples, the glass members 700 (and grooves 1208) may be formed so that straight, non-slanted edges are present, or so that the edges are stepped as in FIG. 6A. More generally, in examples, the glass members 700 (and grooves 1208) may be formed as may be suitable so that the glass members 700 have target dimensions, shapes, volumes, etc. In examples, the grooves 1208 are formed taking into account the optical physics described above with respect to FIGS. 10E and 10F.

The method 1300 includes coupling the first surface of the glass wafer to the semiconductor wafer such that the glass member is vertically aligned with the optical sensor (1306). FIG. 12F is a profile, cross-sectional view of the glass wafer 1202 coupled to semiconductor wafer 1200. Specifically, the top surface 1204 couples to the semiconductor wafer 1200. The wafers may be aligned so that the glass members 700 are vertically aligned with the optical sensors 106, as shown. The glass wafer 1202 may be coupled to the semiconductor wafer 1200 using any suitable technique, such as transparent optical adhesives; direct bonding; surface activated bonding; anodic bonding; eutectic bonding; glass frit bonding; adhesive bonding; thermocompression bonding; reactive bonding; and transient liquid phase diffusion bonding.

The method 1300 includes separating the glass member from the glass wafer (1308). FIG. 12G is a profile, cross-sectional view of the glass members 700 having been separated from each other (e.g., having been separated from the glass wafer 1202). In some examples, the glass members 700 are separated by grinding down the surface 1206 until the grooves 1208 are reached and thus the glass members 700 are singulated, as shown in the transition from FIG. 12F to FIG. 12G. Techniques other than grinding also may be used to perform this singulation process.

The method 1300 includes performing a singulation process on the semiconductor wafer to produce a semiconductor die having the optical sensor and the glass member abutting the optical sensor (1310). FIG. 12H is a profile, cross-sectional view of the structure of FIG. 12G, but with the semiconductor wafer 1200 singulated into individual semiconductor dies 100, as shown. For example, a sawing technique may be used to perform the singulation. The resulting structure is shown in FIG. 12I. The structure of FIG. 12I may be coupled to conductive terminals 800 of a lead frame, as shown in FIG. 12J. Bond wires 802 may be coupled between the conductive terminals 800 and the bond pads 104, as shown in FIG. 12K.

The method 1300 includes positioning the semiconductor die and the glass member in a mold chase such that a top surface of the glass member establishes contact with a member of the mold chase (1312). The method 1300 also includes applying a mold compound inside the mold chase such that the contact between the glass member and the mold chase precludes the mold compound from covering the top surface of the glass member (1314). FIGS. 9A and 9B depict the performance of 1312 and 1314. FIG. 12L is a perspective view of an example optical sensor package 1000 that results from performance of the method 1300.

As explained above, the glass member 700 is formed separately from the rest of the optical sensor package 1000. This permits the glass member 700 to be formed with any suitable properties, including size (e.g., small size). As also explained above, the glass members 700 are used to form cavities in the optical sensor packages 1000. Using small glass members 700 thus results in small cavities. As a result, optical sensor packages 1000 having just one cavity can be made smaller than other optical sensor packages not using the techniques described herein. Similarly, optical sensor packages 1000 can remain the same size as other optical sensor packages not formed using the techniques described herein but can accommodate more cavities (and, thus, more optical sensors) than can optical sensor packages not formed using the techniques described herein. Accordingly, the ratio of optical sensor number to optical sensor package size is substantially increased relative to such ratios in traditional optical sensor packages.

In the foregoing discussion and in the claims, the terms “including” and “comprising” are used in an open-ended fashion, and thus mean “including, but not limited to . . . .” Also, the term “couple” or “couples” means either an indirect or direct connection. Thus, if a first device couples to a second device, that connection may be through a direct connection or through an indirect connection via other devices and connections. Similarly, a device that is coupled between a first component or location and a second component or location may be through a direct connection or through an indirect connection via other devices and connections. An element or feature that is “configured to” perform a task or function may be configured (e.g., programmed or structurally designed) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof. Unless otherwise stated, “about,” “approximately,” or “substantially” preceding a value means +/−10 percent of the stated value.

The above discussion is illustrative of the principles and various embodiments of the present disclosure. Numerous variations and modifications will become apparent to those skilled in the art once the above disclosure is fully appreciated. The following claims should be interpreted to embrace all such variations and modifications.

What is claimed is:

1. An optical sensor package, comprising:
a semiconductor die;
an opaque mold compound covering the semiconductor die and having a cavity;
an optical sensor on the semiconductor die and exposed to the cavity; and
a glass member inside the cavity, the glass member abutting the sensor and a wall of the cavity, the glass member exposed to an exterior environment of the optical sensor package, the glass member having a thickness approximately equivalent to a depth of the cavity.

2. The optical sensor package of claim 1, further comprising an optical adhesive abutting the optical sensor and the glass member.

3. The optical sensor package of claim 1, wherein the glass member is a stepped cylindrical member having two different horizontal diameters.

4. The optical sensor package of claim 1, wherein a volume of the glass member is approximately equal to a volume of the cavity.

5. The optical sensor package of claim 1, wherein the glass member has a first portion and a second portion, the first portion closer to the optical sensor than the second portion, the first portion having a larger horizontal cross-sectional area than the second portion.

6. The optical sensor package of claim 1, wherein the glass member has a convex surface.

7. An optical sensor package, comprising:
a semiconductor die;
an opaque mold compound covering the semiconductor die and having a cavity, the cavity having first and second horizontal cross-sectional areas that differ from each other;
an optical sensor on the semiconductor die and inside the cavity; and
a glass member coupled to the optical sensor and abutting multiple walls of the cavity, the glass member having a same shape as the cavity, the glass member exposed to an exterior environment of the optical sensor package.

8. The optical sensor package of claim 7, wherein the glass member has a horizontal cross-sectional area and thickness such that the optical sensor is able to detect a light ray having an angle of incidence at the optical sensor between 0 and 70 degrees.

9. The optical sensor package of claim 7, further comprising a coat on the glass member, the coat configured to filter light of a target frequency.

10. The optical sensor package of claim 7, wherein the glass member is a glass-filled polymer.

11. The optical sensor package of claim 7, wherein the glass member is a crystal glass member.

12. The optical sensor package of claim 7, wherein the glass member is colored to filter a target color of light.

13. The optical sensor package of claim 7, wherein a volume of the glass member is approximately equal to a volume of the cavity.

14. The optical sensor package of claim 7, wherein the glass member has a convex surface.

15. A method of manufacturing a semiconductor package, comprising:
obtaining a semiconductor die having an optical sensor;
attaching a glass member to the optical sensor;
positioning the semiconductor die and the glass member inside a mold chase;
establishing contact between a member of the mold chase and a top surface of the glass member; and
molding the semiconductor die and the glass member by applying a mold compound inside the mold chase, the contact between the member of the mold chase and the top surface of the glass member preventing the mold compound from flowing onto the top surface of the glass member.

16. The method of claim 15, wherein the mold compound is opaque.

17. The method of claim 15, wherein coupling the glass member to the optical sensor comprises using an optical adhesive.

18. The method of claim 15, wherein the glass member has a stepped or slanted outer surface.

19. The method of claim 15, wherein the glass member has a horizontal cross-sectional area and thickness such that the optical sensor is able to detect a light ray having a 70 degree angle of incidence at the optical sensor.

20. A method, comprising:
providing a semiconductor wafer having an optical sensor;
producing first and second grooves in a first surface of a glass wafer so that the first surface of the glass wafer includes a glass member in between the first and second grooves;
coupling the first surface of the glass wafer to the semiconductor wafer such that the glass member is vertically aligned with the optical sensor;
separating the glass member from the glass wafer;
performing a singulation process on the semiconductor wafer to produce a semiconductor die having the optical sensor and the glass member abutting the optical sensor;
positioning the semiconductor die and the glass member in a mold chase such that a top surface of the glass member establishes contact with a member of the mold chase; and
applying a mold compound inside the mold chase such that the contact between the glass member and the mold chase precludes the mold compound from covering the top surface of the glass member.

21. The method of claim 20, wherein separating the glass member from the glass wafer comprises grinding a second surface of the glass wafer until the glass member separates from the glass wafer, the second surface opposite the first surface.

22. The method of claim 20, wherein the glass member has a slanted or stepped outer surface.

23. The method of claim 20, wherein producing the first and second grooves comprises using an anisotropic etching technique.

24. The method of claim 20, wherein the glass member has a horizontal cross-sectional area and thickness such that the optical sensor is able to detect a light ray having a 70 degree angle of incidence at the optical sensor.
